(19) United States
(12) Patent Application Publication
(10) Pub. No.: US 2008/0054356 A1
(43) Pub. Date: Mar. 6, 2008

(54) Semiconductor device and manufacturing method thereof

(75) Inventor: Eiji Yoshida, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/896,679

(22) Filed: Sep. 5, 2007

(30) Foreign Application Priority Data
Sep. 6, 2006 (JP) 2006-240973

(51) Int. Cl. H01L 29/78; H01L 21/8236

(52) U.S. Cl. 257/344; 438/276; 257/E29.268; 257/E21.631

(57) ABSTRACT

Under a sidewall formed over a side wall of a gate electrode, a low-concentration LDD region and a high-concentration LDD region which is extremely shallow and apart from a region under the gate electrode are formed. Further, a source/drain region is formed outside these LDD regions. Since the extremely shallow high-concentration LDD region is formed under the sidewall, even if hot carriers are accumulated in the sidewall, depletion due to the hot carriers can be suppressed. Further, since the high-concentration LDD region is formed apart from a region under the gate electrode, a transverse electric field in the channel is sufficiently relaxed, so that characteristic deterioration due to a threshold shift can be suppressed.

### CROSS-REFERENCE TO RELATED APPLICATIONS

This application is based upon and claims the benefits of priority from the prior Japanese Patent Application No. 2006-240973, filed on Sep. 6, 2006, the entire contents of which are incorporated herein by reference.

### BACKGROUND OF THE INVENTION

1. Field of the Invention

The present invention relates to a semiconductor device and a manufacturing method thereof. More particularly, the present invention relates to a semiconductor device having a field effect transistor.

2. Description of the Related Art

In a MOS (Metal Oxide Semiconductor) field effect transistor (referred to as a “MOS transistor”), characteristic deterioration due to hot carriers generated by impact ionization frequently becomes a problem. For example, when hot carriers are accumulated in a gate oxide film made of a silicon oxide (SiO₂) film, hot carrier traps and interface states are formed in the film and as a result, a threshold shift occurs. Further, there may occur a phenomenon that when hot carriers are accumulated in a SiO₂ sidewall formed over a side wall of a gate electrode, a surface part of a source/drain region under the sidewall is depleted and as a result, a resistance of the region is caused to increase.

In order to prevent such characteristic deterioration, there is widely used a method where in constructing a MOS transistor, a quality of its gate oxide film is taken into consideration or an LDD (Lightly Doped Drain) region is formed to relax an electric field near the drain. Further, in order to prevent a surface part of the LDD region from being depleted due to accumulation of hot carriers in the sidewall over the LDD region, there may be used a method of increasing an impurity concentration in the LDD region. Further, in order to relax an electric field near the LDD region which is formed to have a high impurity concentration for preventing depletion, there is proposed a method of using a so-called double LDD structure in which a high-concentration LDD region is surrounded by a low-concentration LDD region (see, e.g., Japanese Unexamined Patent Publication No. 2000-307113).

In an advanced SoC (System on Chip), a MOS transistor (referred to as a “high-voltage transistor”) operating at high voltages of 3.3 V, 2.5 V and 1.8 V for I/O devices and a MOS transistor (referred to as a “low-voltage transistor”) operating at low voltages of 1.2 V and 1.0 V for high-performance logic devices are mounted on the same substrate.

In formation of the low-voltage transistor for high-performance logic devices, all the processes other than activation annealing of impurities implanted into a semiconductor substrate must be performed at a low temperature. For example, when forming a sidewall using a SiO₂ film, a SiO₂ film formed at a low temperature of about 500° C. is used. In reality, when forming a sidewall composed of such a low-temperature formed SiO₂ film on the high-voltage transistor side as well as on the low-voltage transistor side, the above-described characteristic deterioration of the high-voltage transistor due to hot carries easily occurs.

FIG. 20 illustrates a characteristic deterioration phenomenon of the high-voltage transistor.

A high-voltage transistor 200 shown in FIG. 20 has the following construction. That is, a gate electrode 203 is formed over a semiconductor substrate 201 through a gate oxide film 202 and a sidewall 204 is formed over a side wall of the gate electrode 203. In the semiconductor substrate 201 under the sidewall 204, an LDD region 205 whose one end on the gate electrode 203 side reaches a region under the gate electrode 203 is formed, and a source/drain region 206 is formed outside the LDD region 205.

When forming the sidewall 204 of the high-voltage transistor 200 using the low-temperature formed SiO₂ film, hot carriers generated by impact ionization are easily accumulated in the sidewall 204. As a result, a surface part of the LDD region 205 is depleted and a resistance of the region 205 increases (in FIG. 20, a depletion layer is indicated by a dotted line and a hot carrier path is indicated by an arrow). This phenomenon occurs more easily when the high-voltage transistor 200 is of an n-channel type.

In order to prevent the depletion in the surface part of the LDD region 205 of the high-voltage transistor 200, it is considered to increase an impurity concentration in the region 205 or to form a double LDD structure as described above.

However, when directly increasing an impurity concentration in the LDD region 205, a transverse electric field in channel is hardly relaxed and as a result, a threshold shift due to accumulation of hot carriers in the gate oxide film 202 easily occurs.

When increasing an impurity concentration in the LDD region 205 under the sidewall 204 and then forming an LDD region with a lower impurity concentration outside the LDD region 205 to form a double LDD structure as described above, it becomes possible to relax such an electric field and to suppress the threshold shift. However, in this case, the low-concentration LDD region largely extends to a region under the gate electrode 203 and as a result, a short-channel resistance of the MOS transistor deteriorates due to the low-concentration LDD region. Further, in the case of adopting the double LDD structure, two ion implantation steps for the formation of the low-concentration LDD region and the formation of the high-concentration LDD region must be performed and therefore, the number of steps is increased and the manufacturing cost is increased.

### SUMMARY OF THE INVENTION

According to one aspect of the present invention, there is provided a semiconductor device having a field-effect transistor. This transistor has a semiconductor substrate, a gate electrode formed over the substrate through a gate insulating film, a sidewall formed over a side wall of the gate electrode, a first impurity region formed in the substrate under the sidewall, a second impurity region formed in the substrate under the sidewall, the region being shallower than the first impurity region and being apart from a region under the gate electrode and a source/drain region formed outside the first and second impurity regions.

According to another aspect of the present invention, there is provided a method of manufacturing a semiconductor device having field effect transistors different in operating voltage. The method has the steps of forming gate electrodes through gate insulating films in a formation region of a high-voltage transistor operating at a higher voltage and in a formation region of a low-voltage transistor operating at a lower voltage of a semiconductor substrate, respectively, ion-implanting impurities into the high-voltage transistor formation region having formed thereover the gate electrode to form a first impurity region; forming a first sidewall over the high-voltage transistor formation region having formed therein the first impurity region; simultaneously ion-implanting impurities into the high-voltage transistor formation region having formed thereover the first sidewall and the low-voltage transistor formation region to form second impurity regions shallower than the first impurity region, respectively, forming second sidewalls over the high-voltage transistor formation region and low-voltage transistor formation region having formed therein the second impurity region, respectively; and ion-implanting impurities into the high-voltage transistor formation region and low-voltage transistor formation region having formed thereover the second sidewalls to form source/drain regions, respectively.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 illustrates principles of the first embodiment.

FIG. 2 illustrates a first ion implantation step of the first embodiment.

FIG. 3 illustrates a second ion implantation step of the first embodiment.

FIG. 4 illustrates a third ion implantation step of the first embodiment.

FIG. 5 shows a relationship between a dose for a high-concentration LDD region of a 3.3 V NMOS transistor and a current deterioration rate.

FIG. 6 illustrates a first ion implantation step of the second embodiment.

FIG. 7 illustrates a second ion implantation step of the second embodiment.

FIG. 8 illustrates a third ion implantation step of the second embodiment.

FIG. 9 illustrates principles of the third embodiment.

FIG. 10 illustrates a first ion implantation step of the third embodiment.

FIG. 11 illustrates a second ion implantation step of the third embodiment.

FIG. 12 illustrates a third ion implantation step of the third embodiment.

FIG. 13 illustrates principles of the fourth embodiment.

FIG. 14 illustrates a first SiO₂ film formation step.

FIG. 15 illustrates a first etching step.

FIG. 16 illustrates a first ion implantation step.

FIG. 17 illustrates a second SiO₂ film formation step.

FIG. 18 illustrates a second ion implantation step.

FIG. 19 illustrates a second etching step.

FIG. 20 illustrates a characteristic deterioration phenomenon of a high-voltage transistor.

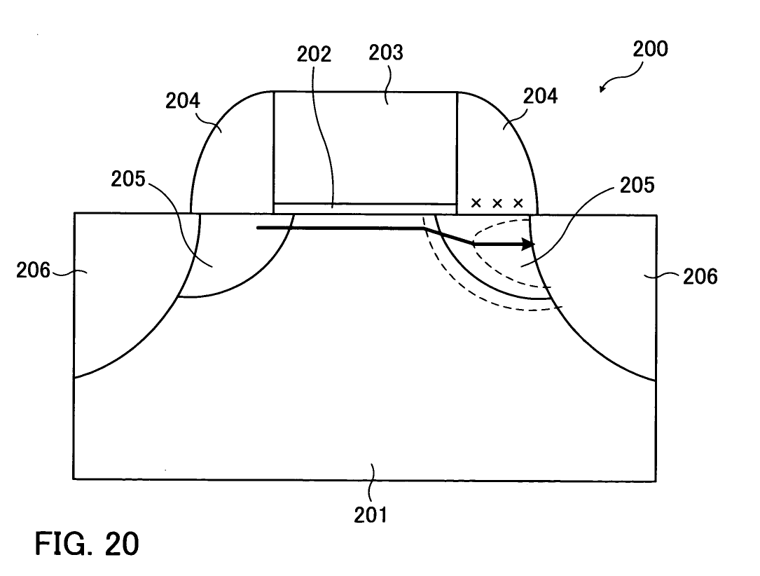

### DESCRIPTION OF THE PREFERRED EMBODIMENTS

Preferred embodiments of the present invention will be described in detail below with reference to the accompanying drawings.

A first embodiment will be first described.

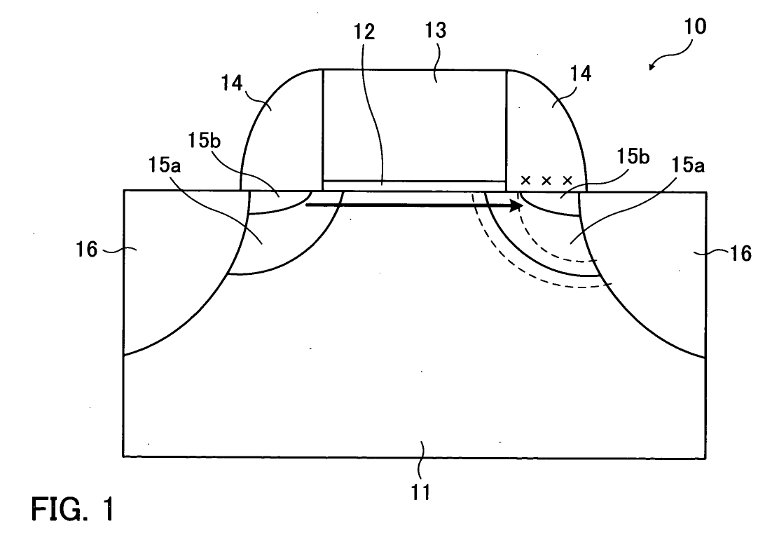

FIG. 1 illustrates principles of the first embodiment.

A MOS transistor 10 shown in FIG. 1 has, for example, the following construction. Over a semiconductor substrate 11 having a predetermined conductivity type, a gate electrode 13 is formed through a gate oxide film 12, and a sidewall 14 is formed over a side wall of the gate electrode 13. A low-concentration LDD region 15a and a high-concentration LDD region 15b having a conductivity type different from that of the semiconductor substrate 11 are formed in the semiconductor substrate 11 under the sidewall 14. The high-concentration LDD region 15b is extremely shallow and its one end on the gate electrode 13 side is formed apart from a region under the gate electrode 13. Further, outside the low-concentration LDD region 15a and the high-concentration LDD region 15b, a source/drain region 16 having the same conductivity type as those of the region 15a and the region 15b is formed.

By forming such an extremely shallow high-concentration LDD region 15b under the sidewall 14, even if hot carriers are generated and accumulated in the sidewall 14 (in FIG. 1, indicated by “X” marks), depletion of the high-concentration LDD region 15b, that is, depletion of a surface part of the LDD region can be suppressed (in FIG. 1, a depletion layer is indicated by dotted lines and a carrier path is indicated by an arrow). Further, the high-concentration LDD region 15b is formed apart from a region under the gate electrode 13. Therefore, a transverse electric field in channel is sufficiently relaxed, so that characteristic deterioration due to threshold shift can be effectively suppressed. In addition thereto, the low-concentration LDD regions 15a on the source and drain sides can be formed with a certain distance between the facing ends of the regions 15a, so that short-channel resistance characteristics can be secured.

This construction is applied, for example, to the case of forming a high-voltage transistor and a low-voltage transistor in the same chip, specifically, to a construction on a high-voltage transistor side. In this case, even when both sidewalls of the high-voltage transistor and the low-voltage transistor are formed using a SiO₂ film simultaneously formed at a low temperature, depletion in the surface part of the LDD region of the high-voltage transistor can be effectively suppressed.

Further, when forming the above-described extremely shallow high-concentration LDD region on the high-voltage transistor side by ion implantation of predetermined impurities, the ion implantation is performed simultaneously with that in forming a source/drain/extension region (simply referred to as an “extension region”) on the low-voltage transistor side. As a result, formation of the high-voltage transistor and the low-voltage transistor can be effectively performed at low cost.

Here, a method of forming the high-voltage transistor and the low-voltage transistor in the same chip will be described in detail.

By taking as an example a case of forming transistors corresponding to two kinds of voltages such as a high-voltage transistor operating at 3.3 V and a low-voltage transistor operating at 1.2 V in the same chip, description will be made here by taking the respective n-channel portions into consideration.

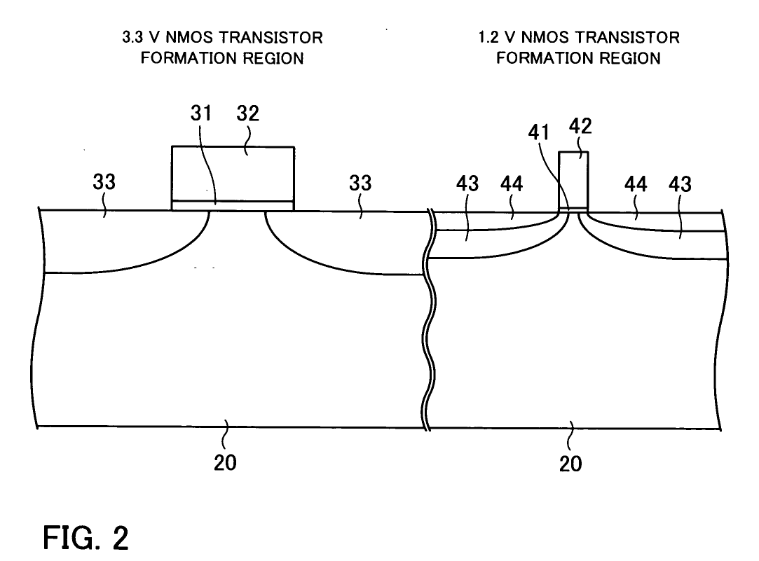

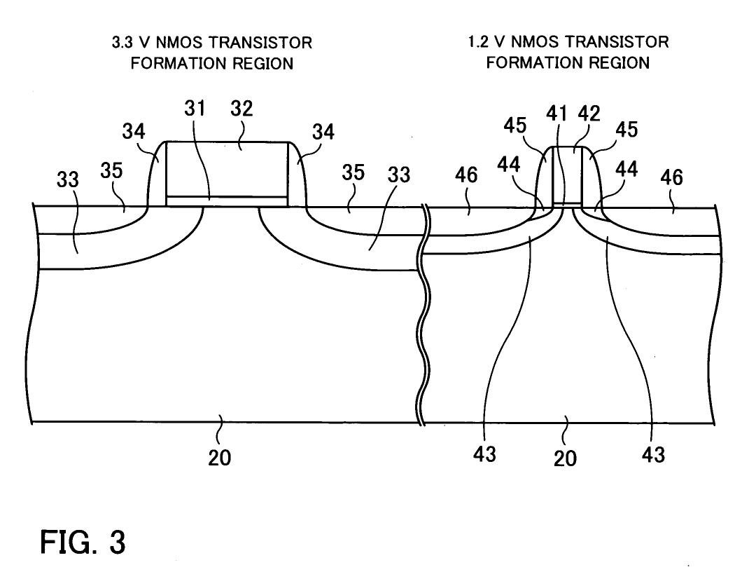

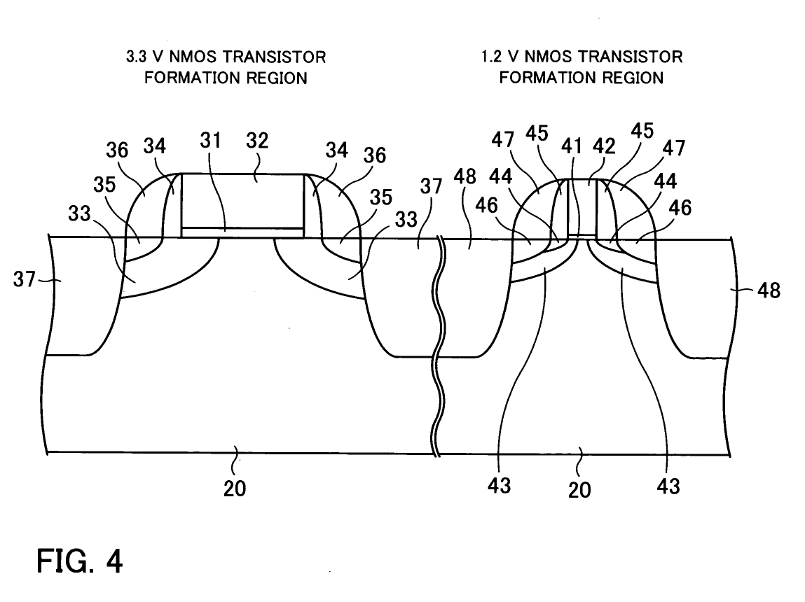

FIG. 2 illustrates a first ion implantation step of the first embodiment, FIG. 3 illustrates a second ion implantation step of the first embodiment, and FIG. 4 illustrates a third ion implantation step of the first embodiment.

First, an element isolation region (not shown) is formed in a silicon (Si) substrate 20 using an STI (Shallow Trench Isolation) method. Then, a SiO₂ film having a predetermined thickness is formed in a predetermined region of the surface using a thermal oxidation method, and polysilicon is deposited over the film. Then, the polysilicon and the SiO₂ film are processed to have predetermined shapes. Thus, gate oxide films 31 and 41 and gate electrodes 32 and 42 are formed in a formation region of an n-channel type MOS transistor corresponding to a 3.3 V power supply (referred to as a “3.3 V NMOS transistor”) and in a formation region of an n-channel type MOS transistor corresponding to a 1.2 V power supply (referred to as a “1.2 V NMOS transistor”) of the same Si substrate 20, respectively, as shown in FIG. 2.

Thereafter, a resist is formed over the formation region of the 1.2 V NMOS transistor (not shown). Then, into the formation region of the 3.3 V NMOS transistor, phosphorus (P) as n-type impurities is ion-implanted using the gate electrode 32 as a mask, and the annealing at about 900 to 1050° C. is performed. Thus, an n-type low-concentration LDD region 33 is formed as an impurity region.

The ion implantation of P for forming the low-concentration LDD region 33 is performed, for example, under the conditions that an acceleration voltage is 15 to 40 keV, a dose is 1×10¹³ to 5×10¹³ cm⁻² and a tilt angle is 0 degree. Alternatively, the ion implantation of P is performed four times under the conditions that an acceleration voltage is 15 to 40 keV, a dose is 2.5×10¹² to 12×10¹² cm⁻² and a tilt angle is 28 degree.

After such ion implantation of P, the resist over the formation region of the 1.2 V NMOS transistor is removed, and the annealing at the above-described predetermined temperature is performed.

Subsequently, a resist is formed over the formation region of the 3.3 V NMOS transistor (not shown). Then, into the formation region of the 1.2 V NMOS transistor, boron (B) as a p-type impurity is ion-implanted using the gate electrode 42 as a mask to form a p-type pocket region 43 as an impurity region. Further, arsenic (As) as an n-type impurity is ion-implanted to form an n-type extension region 44 as an impurity region.

The ion implantation of boron (B) for forming the pocket region 43 is performed four times, for example, under the conditions that an acceleration voltage is 5 to 10 keV, a dose is 1×10¹² to 15×10¹² cm⁻² and a tilt angle is 28 degree.

The ion implantation of arsenic (As) for forming the extension region 44 is performed, for example, under the conditions that an acceleration voltage is 3 keV, a dose is 1×10¹⁴ to 20×10¹⁴ cm⁻² and a tilt angle is 0 degree.

After the ion implantation of B and As, the resist over the formation region of the 3.3 V NMOS transistor is removed.

The above-described annealing performed during the formation of the low-concentration LDD region 33 may be performed after the ion implantation for forming the pocket region 43 and the extension region 44 (after removal of the resist) without being performed at that time.

Subsequently, using a low-temperature CVD (Chemical Vapor Deposition) method at about 500 to 600° C., a SiO₂ film is deposited over the entire surface and dry-etched. Thus, thin sidewalls 34 and 45 having a thickness of, for example, about 5 to 20 nm are formed over the side walls of the gate electrodes 32 and 42, respectively, as shown in FIG. 3.

Thereafter, As is ion-implanted using as masks the gate electrodes 32 and 42 and the sidewalls 34 and 45 formed over the side walls of the electrodes 32 and 42. The ion implantation conditions are, for example, set such that an acceleration voltage is 1 to 7 keV, a dose is 5×10¹⁴ to 20×10¹⁴ cm⁻² and a tilt angle is 0 degree. By this ion implantation of As, an extremely shallow n-type high-concentration LDD region 35 as an impurity region is formed in the formation region of the 3.3 V NMOS transistor. Further, an additional n-type extension region 46 as an impurity region is formed outside the previously formed extension region 44 in the formation region of the 1.2 V NMOS transistor.

Thus, in the first embodiment, the ion implantation for forming the extension region 46 in the formation region of the 1.2 V NMOS transistor is simultaneously performed by the same process as that of the ion implantation for forming the high-concentration LDD region 35 in the formation region of the 3.3 V NMOS transistor.

Subsequently, using a low-temperature CVD method at about 500 to 600° C., a SiO₂ film is deposited over the entire surface and dry-etched. Thus, thick sidewalls 36 and 47 having, for example, a thickness of about 50 to 90 nm are formed outside the previously formed sidewalls 34 and 45, respectively, as shown in FIG. 4.

Thereafter, using as masks the gate electrode 32 and the sidewalls 34 and 36 as well as the gate electrode 42 and the sidewalls 45 and 47, n-type impurities are ion-implanted to form n-type source/drain regions 37 and 48, respectively.

Thereafter, activation annealing at about 1000 to 1200° C. is performed to form silicide layers (not shown) over the surfaces of the gate electrodes 32 and 42 and the source/drain regions 37 and 48 by a silicide process. Thus, fundamental structures of the 3.3 V NMOS transistor and the 1.2 V NMOS transistor are completed. Hereafter, a chip having formed thereon the 3.3 V NMOS transistor and the 1.2 V NMOS transistor may be completed through the formations of interlayer insulating films, contact electrodes and wiring layers.

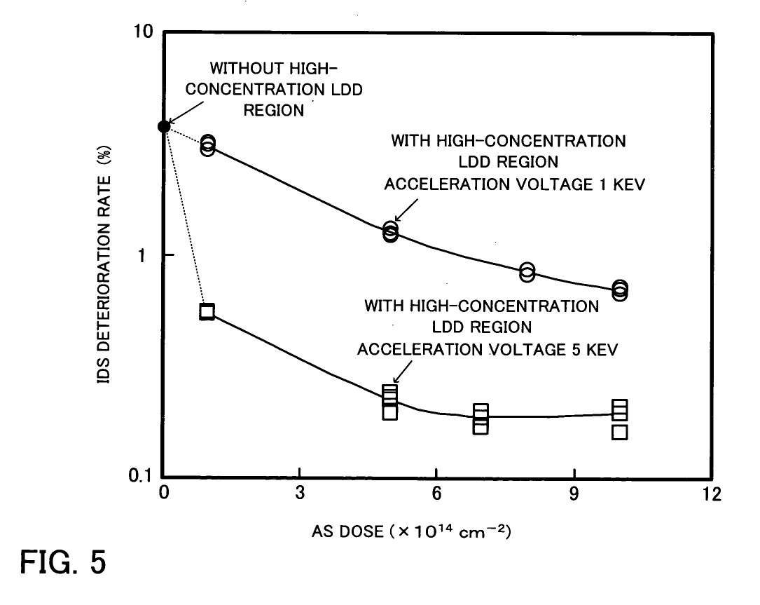

FIG. 5 shows a relationship between a dose for the high-concentration LDD region of the 3.3 V NMOS transistor and a current deterioration rate. In FIG. 5, the horizontal axis represents the dose (×10¹⁴ cm⁻²) in the ion implantation of As performed for formation of the high-concentration LDD region 35 and the vertical axis represents the deterioration rate (%) of a current Ids flowing between the drain and the source (between the source/drain regions 37). FIG. 5 plots the respective measurement results when setting an acceleration voltage in the ion implantation of As performed for formation of the high-concentration LDD region 35 to 1 keV and 5 keV.

First, when forming no extremely shallow high-concentration LDD region 35 in the formation region of the 3.3 V NMOS transistor (the dose: 0 cm⁻²), the current Ids deteriorates by about 4% in terms of the specification.

In contrast, when forming the high-concentration LDD region 35 in the formation region of the 3.3 V NMOS transistor, the deterioration rate of the current Ids decreases in any case where the acceleration voltages in the ion implantation of As are 1 keV and 5 keV. Further, a reducing effect of the deterioration rate in the current Ids tends to increase with the increase in the dose of As in this measuring range. For example, the deterioration rate of the current Ids can be suppressed to about 0.15% under the conditions where the acceleration voltage is 5 keV and the dose is 1×10¹⁵ cm⁻².

Thus, by forming the extremely shallow high-concentration LDD region 35 in the formation region of the 3.3 V NMOS transistor, even if hot carriers are generated and accumulated in the sidewall 36, depletion of the surface part of the LDD region due to hot carriers is suppressed, so that the deterioration of the current Ids can be effectively suppressed.

The ion implantation of AS for forming the extremely shallow high-concentration LDD region 35 is performed using as masks the gate electrode 32 and the thin sidewall 34 formed over the side wall of the electrode 32. Accordingly, As is ion-implanted apart from a region under the gate electrode 32 by a thickness of this sidewall 34. Therefore, the high-concentration LDD region 35 can be formed apart from a region under the gate electrode 32. As a result, a transverse electric field in channel is sufficiently relaxed, so that the generation of hot carriers and the threshold shift due to the hot carries can be effectively suppressed.

Further, the ion implantation of As for forming the extremely shallow high-concentration LDD region 35 can be performed by the same process as that in the ion implantation for forming the extension region 46 of the 1.2 V NMOS transistor. Therefore, a chip having formed thereon these MOS transistors can be efficiently formed at low cost. In this case, an impurity profile in the high-concentration LDD region 35 of the 3.3 V NMOS transistor and that in the extension region 46 of the 1.2 V NMOS transistor are the same.

The conditions for the ion implantation of As for forming the high-concentration LDD region 35 of the 3.3 V NMOS transistor may be set in consideration of the conditions for the simultaneously performed ion implantation for forming the extension region 46 of the 1.2 V NMOS transistor, the results as shown in FIG. 5 and the demand characteristics of the chip having formed thereon these MOS transistors.

In the first embodiment, an n-channel portion of the MOS transistor is described. A p-channel portion thereof may be formed in parallel with the formation of the n-channel portion in accordance with the conventional method.

Next, a second embodiment will be described.

In this second embodiment, description will be made on the case of applying the principles of the first embodiment to a chip having formed thereon MOS transistors each corresponding to three kinds of voltages.

By taking as an example a case of forming MOS transistors corresponding to three kinds of voltages such as a high-voltage MOS transistor operating at 3.3 V, a high-voltage MOS transistor operating at 1.8 V and a low-voltage MOS transistor operating at 1.2 V in the same chip, description will be made here by taking the respective n-channel portions into consideration.

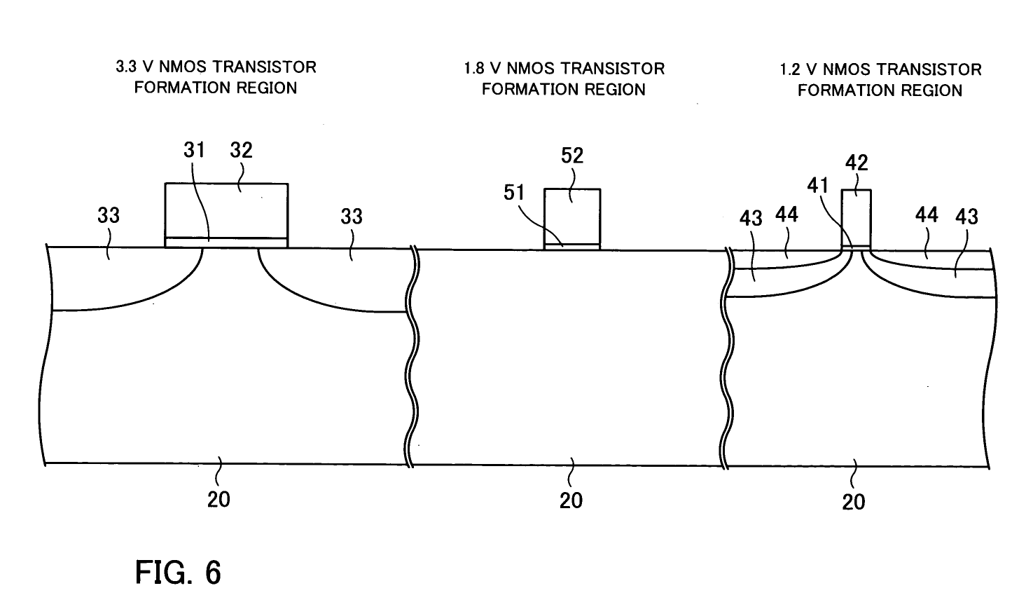

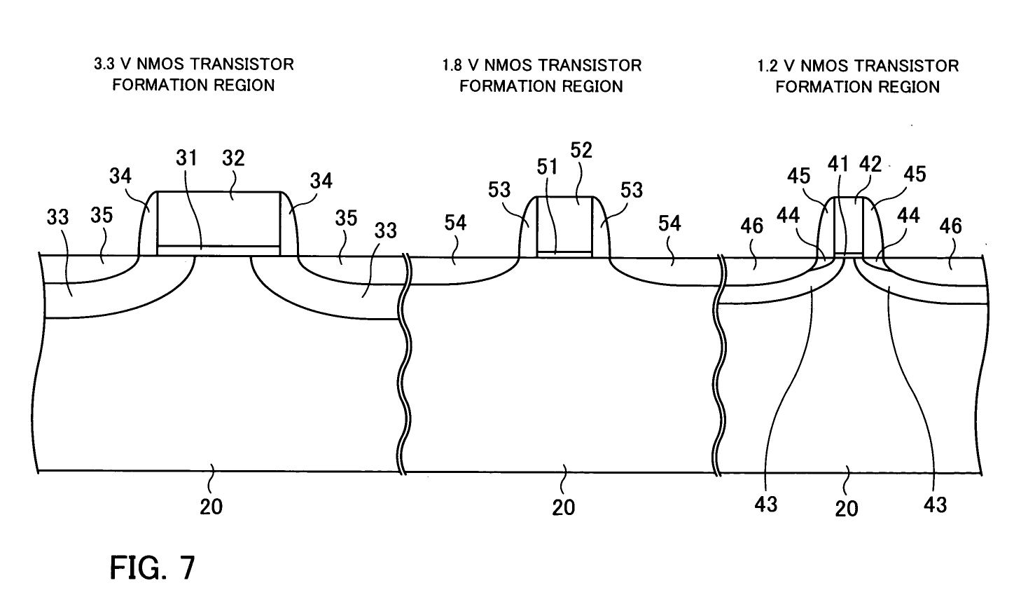

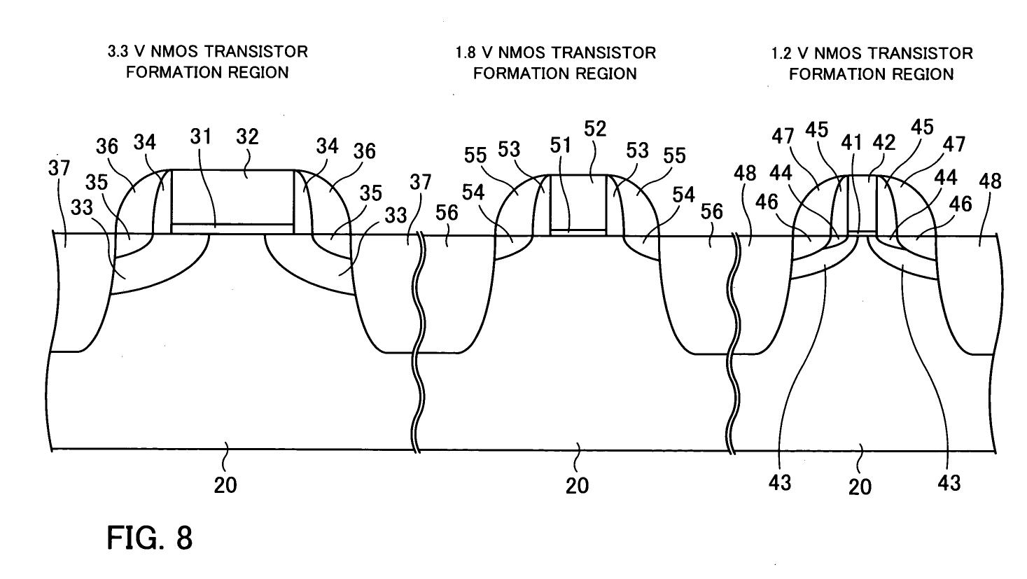

FIG. 6 illustrates a first ion implantation step of the second embodiment, FIG. 7 illustrates a second ion implantation step of the second embodiment, and FIG. 8 illustrates a third ion implantation step of the second embodiment. In FIGS. 6 to 8, the same elements as those in FIGS. 2 to 4 are indicated by the same reference numerals as in FIGS. 2 to 4 and the detailed description is omitted.

First, an element isolation region (not shown) is formed in a silicon (Si) substrate 20. Then, a SiO₂ film having a predetermined thickness is formed in a predetermined region of the surface using a thermal oxidation method, and polysilicon is accumulated over the film. Then, the polysilicon and the SiO₂ film are processed to have predetermined shapes. Thus, gate oxide films 31, 51 and 41 and gate electrodes 32, 52 and 42 are formed in a formation region of an 3.3 V NMOS transistor corresponding to a 3.3 V power supply, in a formation region of an n-channel type MOS transistor corresponding to a 1.8 V power supply (referred to as a “1.8 V NMOS transistor”) and in a formation region of a 1.2 V NMOS transistor corresponding to a 1.2 V power supply of the same substrate 20, respectively, as shown in FIG. 6.

Thereafter, a resist is formed over the formation region of the 1.8 V NMOS transistor and the 1.2 V NMOS transistor (not shown). Then, into a formation region of the 3.3 V NMOS transistor, phosphorus (P) is ion-implanted using the gate electrode 32 as a mask under predetermined conditions as described in the first embodiment, and the annealing at a predetermined temperature is performed. Thus, an n-type low-concentration LDD region 33 is formed as an impurity region. After such ion implantation of P, the resists over the formation regions of the 1.8 V NMOS transistor and the 1.2 V NMOS transistor are removed.

Subsequently, resists are formed over the formation regions of the 3.3 V NMOS transistor and the 1.8 V NMOS transistor (not shown). Then, into the formation region of the 1.2 V NMOS transistor, boron (B) is ion-implanted using the gate electrode 42 as a mask to form a p-type pocket region 43 as an impurity region. Further, arsenic (As) is ion-implanted to form an n-type extension region 44 as an impurity region. The ion implantation of B and the ion implantation of As are respectively performed under the predetermined conditions as described in the first embodiment.

After the ion implantation of B and As, the resists over the formation regions of the 3.3 V NMOS transistor and the 1.8 V NMOS transistor are removed.

The above-described annealing performed during the formation of the low-concentration LDD region 33 may be performed after the ion implantation for forming the pocket region 43 and the extension region 44 (after removal of the resist) without being performed at that time.

Subsequently, using a low-temperature CVD method at about 500 to 600° C., a SiO₂ film is deposited over the entire surface and dry-etched. Thus, sidewalls 34, 53 and 45 having a thickness of, for example, about 5 to 20 nm are formed over the side walls of the gate electrodes 32, 52 and 42, respectively, as shown in FIG. 7.

Thereafter, As is ion-implanted using as masks the gate electrodes 32, 52 and 42 and the sidewalls 34, 53 and 45 formed over the side walls of the electrodes 32, 52 and 42 under the above-described predetermined conditions as described in the first embodiment. By this ion implantation of As, an extremely shallow n-type high-concentration LDD region 35 as an impurity region is formed in the formation region of the 3.3 V NMOS transistor. Further, an n-type LDD region 54 as an impurity region is formed in the formation region of the 1.8 V NMOS transistor. Further, an n-type extension region 46 as an impurity region is formed in the formation region of the 1.2 V NMOS transistor.

Subsequently, using a low-temperature CVD method at about 500 to 600° C., a SiO₂ film is deposited over the entire surface and dry-etched. Thus, sidewalls 36, 55 and 47 having a thickness of, for example, about 50 to 90 nm are formed outside the sidewalls 34, 53 and 45, respectively, as shown in FIG. 8.

Thereafter, using as masks the gate electrode 32 and the sidewalls 34, 36, the gate electrode 52 and the sidewalls 53, 55 as well as the gate electrode 42 and the sidewalls 45, 47, n-type impurities are ion-implanted to form n-type source/drain regions 37, 56 and 48.

Thereafter, the activation annealing at about 1000 to 1200° C. is performed to form silicide layers (not shown) over the surfaces of the gate electrodes 32, 52 and 42 and the source/drain regions 37, 56 and 48. Thus, fundamental structures of the 3.3 V NMOS transistor, the 1.8 V NMOS transistor and the 1.2 V NMOS transistor are completed. Hereafter, a chip having formed thereon the 3.3 V NMOS transistor, the 1.8 V NMOS transistor and the 1.2 V NMOS transistor may be completed through the formations of interlayer insulating films, contact electrodes and wiring layers.

Thus, in the second embodiment, the ion implantation for forming the high-concentration LDD region 35 in the formation region of the 3.3 V NMOS transistor, the ion implantation for forming the LDD region 54 in the formation region of the 1.8 V NMOS transistor, and the ion implantation for forming the extension region 46 in the formation region of the 1.2 V NMOS transistor are simultaneously performed by the same process as shown in FIG. 7. Therefore, a chip having formed thereon these MOS transistors corresponding to three kinds of voltages can be efficiently formed at low cost.

In the second embodiment, an n-channel portion of the MOS transistor is described. A p-channel portion thereof may be formed in parallel with the formation of the n-channel portion in accordance with the conventional method.

Next, a third embodiment will be described.

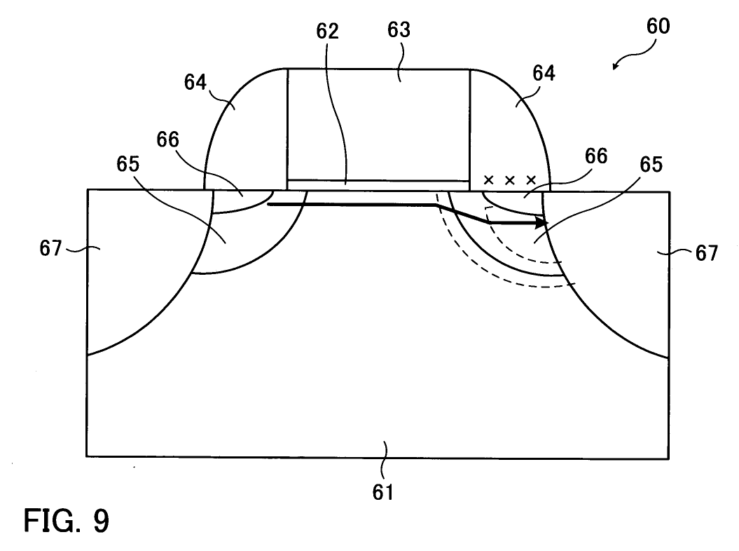

FIG. 9 illustrates principles of the third embodiment.

A MOS transistor 60 shown in FIG. 9 has, for example, the following structure. Over a semiconductor substrate 61 having a predetermined conductivity type, a gate electrode 63 is formed through a gate oxide film 62, and a sidewall 64 is formed over a side wall of the gate electrode 63. An LDD region 65 having a conductivity type different from that of the semiconductor substrate 61 and an extremely shallow counter region 66 having a conductivity type (the same as that of the semiconductor substrate 61) different from that of this LDD region 65 are formed within the semiconductor substrate 61 under the sidewall 64. Further, a source/drain region 67 having the same conductivity type as that of the LDD region 65 is formed outside the LDD region 65 and the counter region 66.

By forming such an extremely shallow counter region 66 in a surface part of the LDD region 65 under the sidewall 64, the surface part of the region 65 becomes a previously depleted state. Accordingly, even if hot carriers are generated and accumulated in the sidewall 64, the surface part of the LDD region 65 is prevented from being depleted (or scarcely depleted), so that characteristic deterioration of the MOS transistor 60 due to hot carriers can be suppressed. When the whole LDD region 65 is depleted, characteristics of the MOS transistor 60 are dramatically deteriorated. Therefore, the counter region 66 is formed only in the extremely shallow surface part of the LDD region 65.

Note, however, that in this case, a path of hot carriers on the drain side is formed apart from an interface between the semiconductor substrate 61 and the sidewall 64 (in FIG. 9, indicated by an arrow) from the beginning and a resistance of the LDD region 65 increases. Further, note that as the impurity concentration in the counter region 66 is more increased or the counter region 66 is made deeper, such increase in resistance is more easily caused.

By a low-temperature process technology and an oxide thin film technology, a recent high-voltage transistor can obtain a large current as compared with a previous one. In forming the high-voltage transistor using such technologies, a method of decreasing the impurity concentration in the LDD region and intentionally increasing the resistance of the region to suppress the current is often performed to match its performance with that of a previous transistor, depending on the use thereof.

Accordingly, for example, as long as a level canceling a current increase portion obtained in using such technologies, when forming the counter region 66 with resistance increase, the MOS transistor 60 having a constant characteristic and suppressed in characteristic deterioration due to hot carriers can be obtained.

The construction as shown in FIG. 9 is applied, for example, to the case of forming a high-voltage transistor and a low-voltage transistor in the same chip, specifically, to a construction on the high-voltage transistor side. In this case, even when both sidewalls of the high-voltage transistor and the low-voltage transistor are formed using a SiO₂ film simultaneously formed at a low temperature, depletion of the LDD region of the high-voltage transistor can be effectively suppressed.

Further, when forming the above-described extremely shallow counter region on the high-voltage transistor side by ion implantation of predetermined impurities, the ion implantation is performed simultaneously with that in forming an extension region on the low-voltage transistor side. As a result, formation of the high-voltage transistor and the low-voltage transistor can be efficiently performed at low cost.

Here, the above-described principles will be described in detail by taking as an example a case of applying the principles to a chip having formed thereon the high-voltage transistor and the low-voltage transistor.

Description will be made here by taking as an example a case of forming transistors corresponding to two kinds of voltages such as a high-voltage transistor operating at 3.3 V and a low-voltage transistor operating at 1.2 V in the same chip.

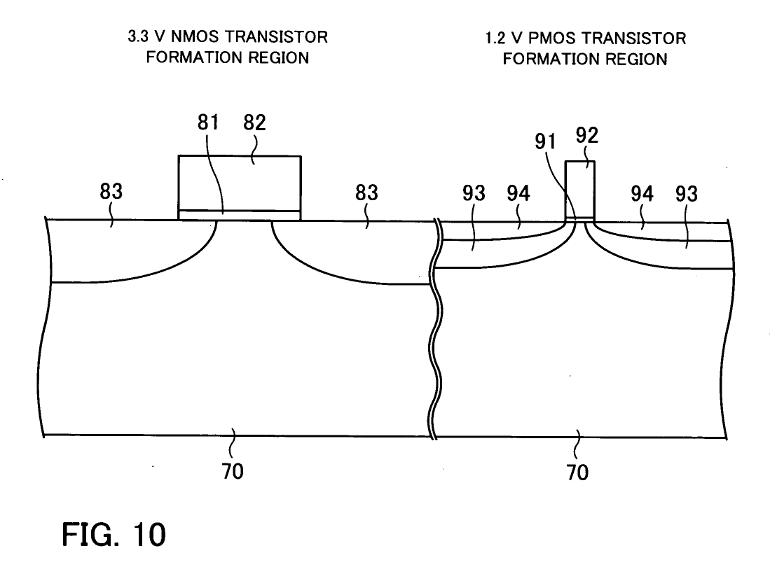

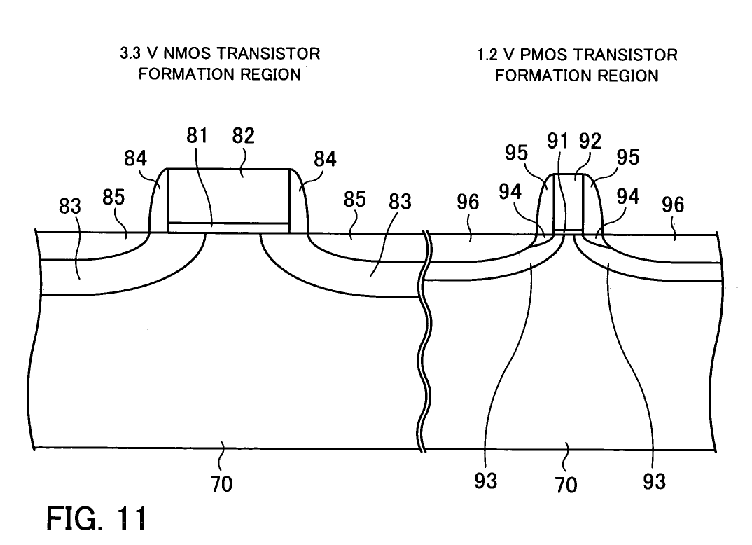

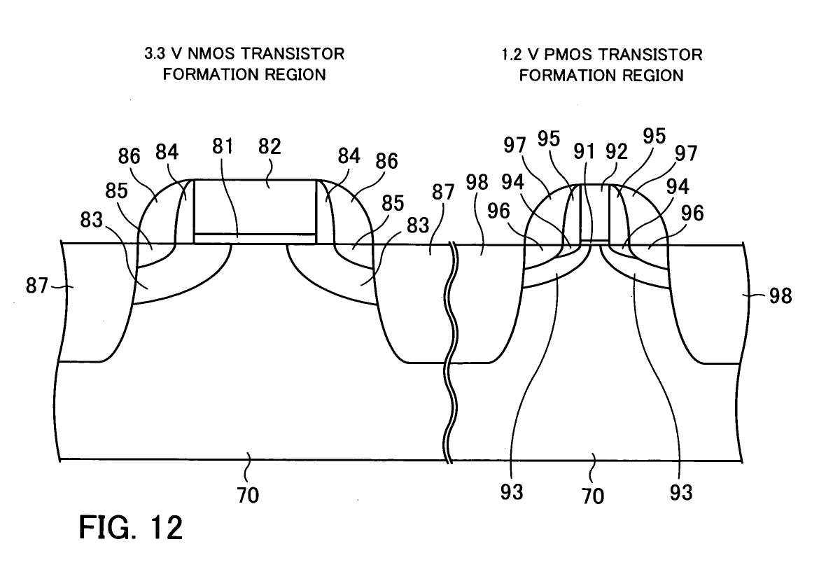

FIG. 10 illustrates a first ion implantation step of the third embodiment, FIG. 11 illustrates a second ion implantation step of the third embodiment, and FIG. 12 illustrates a third ion implantation step of the third embodiment.

First, an element isolation region (not shown) is formed in a silicon (Si) substrate 70 using an STI method. Then, a SiO₂ film having a predetermined thickness is formed in a predetermined region of the surface using a thermal oxidation method, and polysilicon is deposited over the film. Then, the polysilicon and the SiO₂ film are processed to have predetermined shapes. Thus, gate oxide films 81 and 91 and gate electrodes 82 and 92 are formed in a formation region of a 3.3 V NMOS transistor corresponding to a 3.3 V power supply and in a formation region of a p-channel type MOS transistor (1.2 V PMOS transistor) corresponding to a 1.2 V power supply of the same Si substrate 70, respectively, as shown in FIG. 10.

Thereafter, a resist is formed over the formation region of the 1.2 V PMOS transistor (not shown). Then, into the formation region of the 3.3 V NMOS transistor, phosphorus (P) is ion-implanted using the gate electrode 82 as a mask, and the annealing is performed. Thus, an n-type LDD region 83 is formed as an impurity region.

The ion implantation of P at this time is performed, for example, under the conditions that an acceleration voltage is 15 to 40 keV, a dose is 1×10¹³ to 5×10¹³ cm⁻² and a tilt angle is 0 degree. Alternatively, the ion implantation of P is performed four times under the conditions that an acceleration voltage is 15 to 40 keV, a dose is 2.5×10¹² to 12×10¹² cm⁻² and a tilt angle is 28 degree. After such ion implantation of P, the resist over the formation region of the 1.2 V PMOS transistor is removed and the annealing is performed at about 900 to 1050° C.

Subsequently, a resist is formed over the formation region of the 3.3 V NMOS transistor (not shown). Then, into the formation region of the 1.2 V PMOS transistor, P or As is ion-implanted using the gate electrode 92 as a mask to form an n-type pocket region 93 as an impurity region. Further, B is ion-implanted to form a p-type extension region 94 as an impurity region.

The ion-implantation of P for forming the pocket region 93 is performed four times, for example, under the conditions that an acceleration voltage is 20 to 40 keV, a dose is 2×10¹² to 10×10¹² cm⁻² and a tilt angle is 28 degree. Further, the ion-implantation of As for forming the pocket region 93 is performed four times, for example, under the conditions that an acceleration voltage is 30 to 60 keV, a dose is 2×10¹² to 10×10¹² cm⁻² and a tilt angle is 28 degree.

Further, the ion implantation of B for forming the extension region 94 is performed under the conditions that, for example, an acceleration voltage is 0.6 keV or less, a dose is 1×10¹⁵ cm⁻² or less and a tilt angle is 0 degree.

After such ion implantation, the resist over the formation region of the 3.3 V NMOS transistor is removed.

The above-described annealing performed during the formation of the low-concentration LDD region 83 may be performed after the ion implantation for forming the pocket region 93 and the extension region 94 (after removal of the resist) without being performed at that time.

Subsequently, using a low-temperature CVD (Chemical Vapor Deposition) method at about 500 to 600° C., a SiO₂ film is deposited over the entire surface and dry-etched. Thus, the sidewalls 84 and 95 having a thickness of, for example, about 5 to 20 nm are formed over the side walls of the gate electrodes 82 and 92, respectively, as shown in FIG. 11.

Thereafter, B is ion-implanted using as masks the gate electrodes 82 and 92 and the sidewalls 84 and 95. The ion implantation conditions are set such that, for example, an acceleration voltage is 0.3 to 1 keV, a dose is 5×10¹⁴ to 20×10¹⁴ cm⁻² and a tilt angle is 0 degree. By this ion implantation of B, an extremely shallow p-type counter region 85 as an impurity region is formed in the formation region of the 3.3 V NMOS transistor. Further, a p-type extension region 96 as an impurity region is formed in the formation region of the 1.2 V PMOS transistor.

Subsequently, using a low-temperature CVD method at about 500 to 600° C., a SiO₂ film is deposited over the entire surface and dry-etched. Thus, sidewalls 86 and 97 having a thickness of, for example, about 50 to 90 nm are formed outside the sidewalls 84 and 95, respectively, as shown in FIG. 12.

Thereafter, n-type impurity ion implantation using as masks the gate electrode 82 and the sidewalls 84 and 86, and p-type impurity ion implantation using as masks the gate electrode 92 and the sidewalls 95 and 97 are respectively performed to form an n-type source/drain region 87 and a p-type source/drain region 98, respectively.

Thereafter, the activation annealing at about 1000 to 1200° C. is performed to form silicide layers (not shown) over the surfaces of the gate electrodes 82 and 92 and the source/drain regions 87 and 98. Thus, fundamental structures of the 3.3 V NMOS transistor and the 1.2 V PMOS transistor are completed. Hereafter, a chip having formed thereon the 3.3 V NMOS transistor and the 1.2 V PMOS transistor may be completed through the formations of interlayer insulating films, contact electrodes and wiring layers.

Thus, in the third embodiment, the counter region 85 is formed under the sidewall 86 of the 3.3 V NMOS transistor. As a result, there can be effectively suppressed characteristic deterioration due to hot carriers, which easily occurs particularly in the n-channel type MOS transistor operating at a high voltage.

Further, in the third embodiment, the ion implantation for forming the extension region 96 in the formation region of the 1.2 V PMOS transistor is performed by the same process as that in the ion implantation for forming the counter region 85 in the formation region of the 3.3 V NMOS transistor, as shown in FIG. 11. Therefore, a chip having formed thereon these MOS transistors corresponding to two kinds of voltages can be efficiently formed at low cost.

In the third embodiment, portions of the 3.3 V NMOS transistor and the 1.2 V PMOS transistor are described. A p-channel portion and n-channel portion of each transistor may be formed in parallel with each other in accordance with the conventional method.

Next, a fourth embodiment will be described.

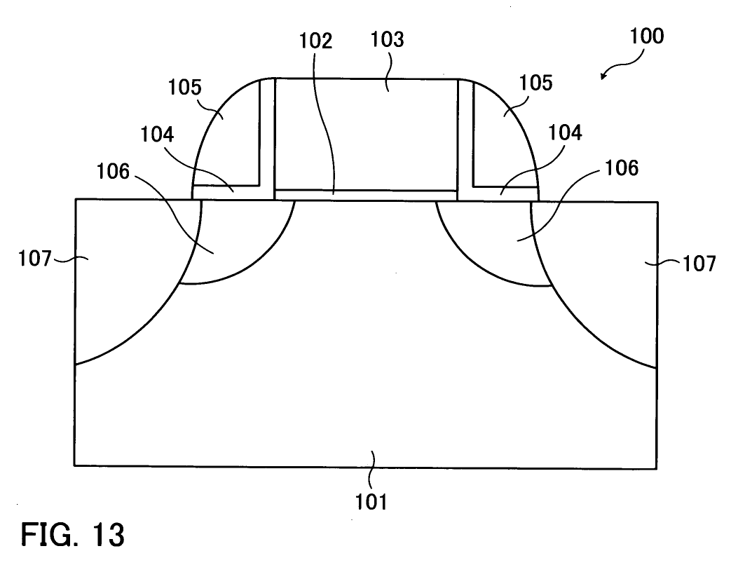

FIG. 13 illustrates principles of the fourth embodiment.

A MOS transistor 100 shown in FIG. 13 has the following structure. Over a semiconductor substrate 101, a gate electrode 103 is formed through a gate oxide film 102, and two layers of sidewalls 104 and 105 having different film qualities are formed over a side wall of the gate electrode 103. The inner sidewall 104 is formed over a side wall of the gate electrode 103 and the semiconductor substrate 101, and the outer sidewall 105 is formed over this sidewall 104. An LDD region 106 is formed within the semiconductor substrate 101 under the inner sidewall 104 and a source/drain region 107 is formed outside the LDD region 106.

In such a MOS transistor 100, the inner sidewall 104 over the gate electrode 103 and the semiconductor substrate 101 is composed of a SiO₂ film formed using the thermal oxidation method or the high-temperature CVD method. Further, the sidewall 105 formed over the sidewall 104 is composed of a SiO₂ film formed using the low-temperature CVD method.

When using the thermal oxidation method or the high-temperature CVD method, a dense SiO₂ film can be formed. Therefore, when such a SiO₂ film is used for a sidewall, hot carriers are hardly accumulated in the sidewall. Accordingly, when forming the sidewall 104 between the LDD region 106 and the low-temperature formed sidewall 105 using the thermal oxidation method or the high-temperature CVD method, even if hot carriers are generated, accumulation of the hot carriers in the sidewall 104 is suppressed. As a result, depletion of the surface part of the LDD region 106 can be suppressed.

Here, the above-described principles will be described in detail by taking as an example a case of applying the principles to a chip having formed thereon the high-voltage transistor and the low-voltage transistor.

Description will be made here by taking as an example a case of forming transistors corresponding to two kinds of voltages such as a high-voltage transistor operating at 3.3 V and a low-voltage transistor operating at 1.2 V in the same chip.

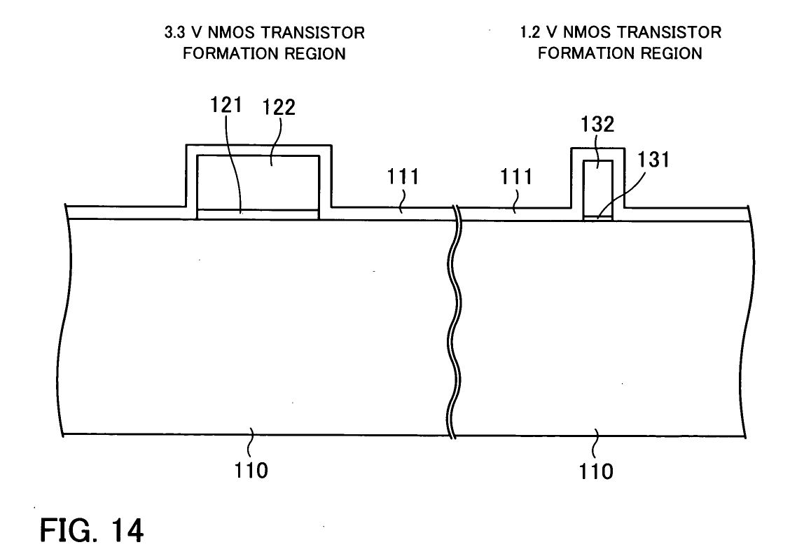

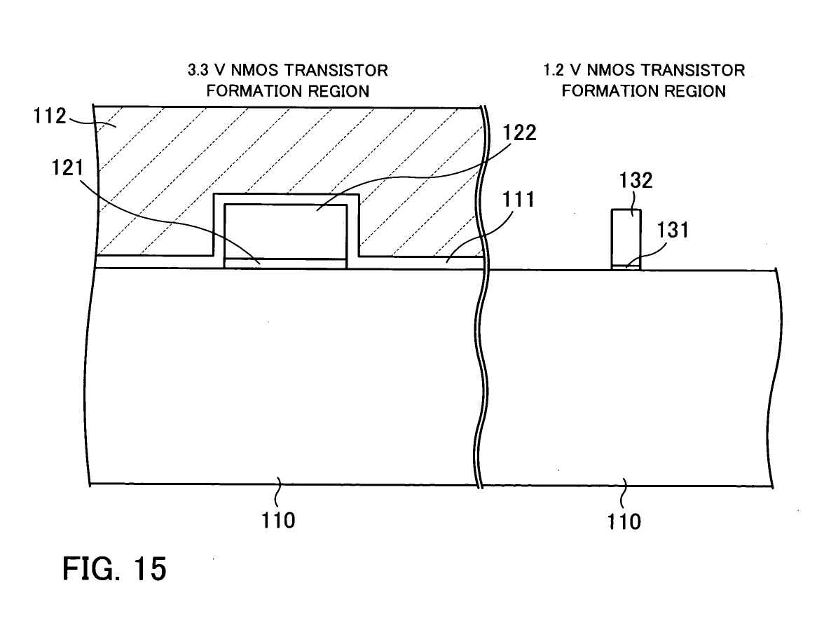

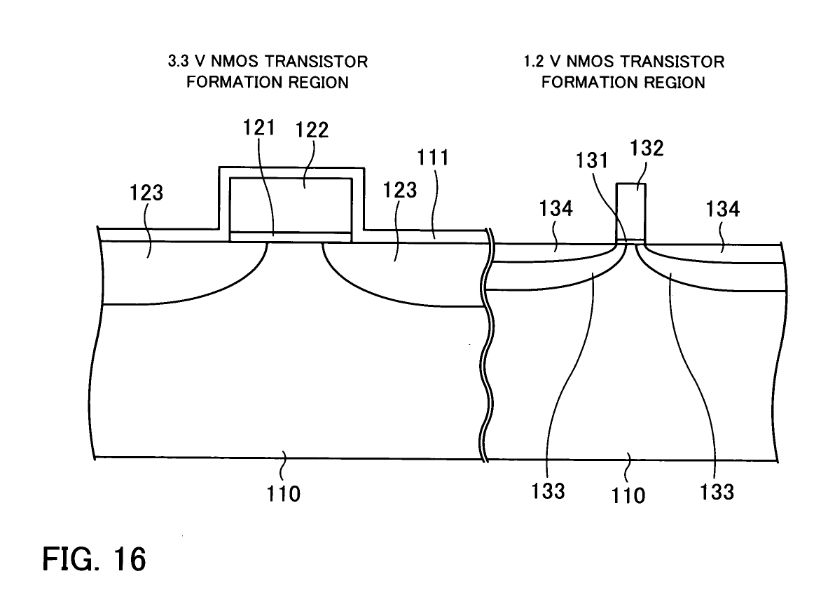

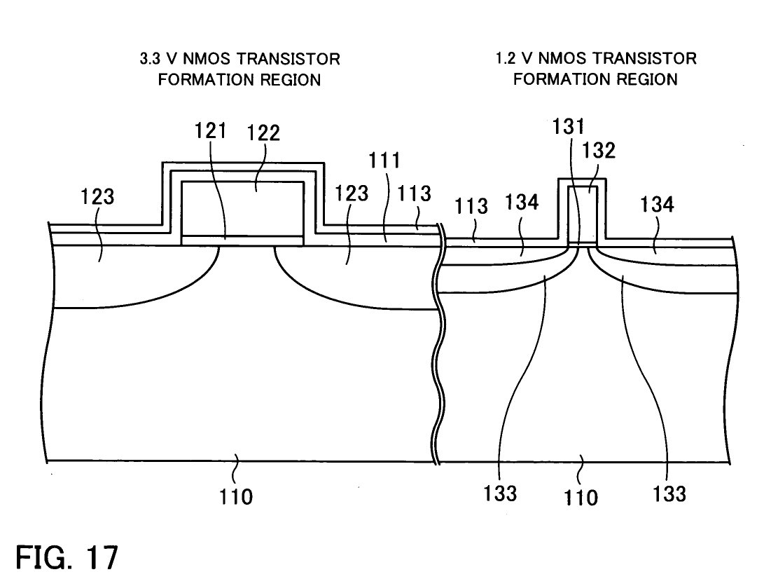

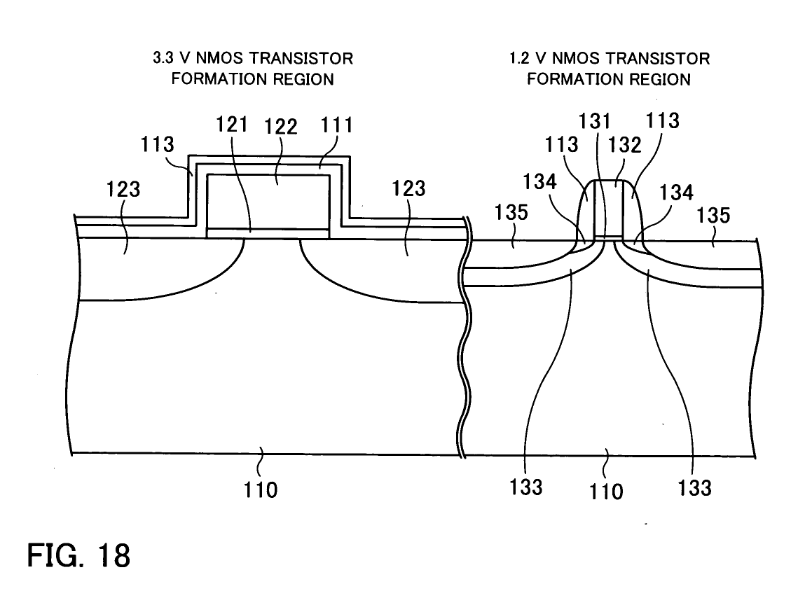

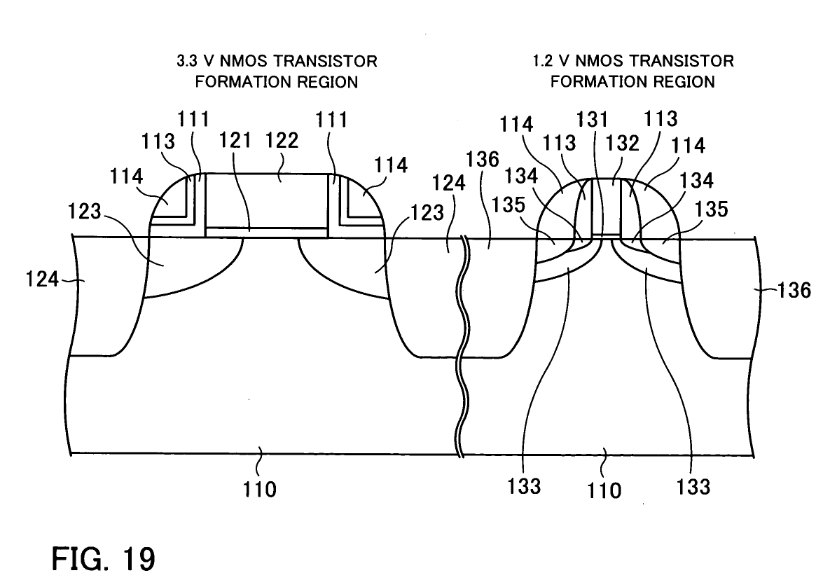

FIG. 14 illustrates a first SiO₂ film formation step, FIG. 15 illustrates a first etching step, FIG. 16 illustrates a first ion implantation step, FIG. 17 illustrates a second SiO₂ film formation step, FIG. 18 illustrates a second ion implantation step, and FIG. 19 illustrates a second etching step.

First, an element isolation region (not shown) is formed in a silicon (Si) substrate 110 using an STI method. Then, a SiO₂ film having a predetermined thickness is formed in a predetermined region of the surface using the thermal oxidation method, and polysilicon is deposited over the film. Then, the polysilicon and the SiO₂ film are processed to have predetermined shapes. Thus, gate oxide films 121 and 131 and gate electrodes 122 and 132 are formed in a formation region of a 3.3 V NMOS transistor corresponding to a 3.3 V power supply and in a formation region of a 1.2 V NMOS transistor corresponding to a 1.2 V power supply of the same Si substrate 110, respectively, as shown in FIG. 14.

Thereafter, a SiO₂ film 111 having a thickness of about 3 nm is formed over the entire surface using the thermal oxidation method or the high-temperature CVD method (600° C. or more).

Subsequently, as shown in FIG. 15, a resist 112 is formed over the formation region of the 3.3 V NMOS transistor, and the SiO₂ film 111 in the formation region of the 1.2 V NMOS transistor is removed by the dry etching and the wet etching. At this time, the SiO₂ film 111 as the sidewall may remain over the side wall of the gate electrode 132 (not shown). Note, however, that in the 1.2 V NMOS transistor, the ion implantation at a low acceleration voltage must be performed to form an extremely shallow junction and therefore, the SiO₂ film 111 over the Si substrate 110 is removed by the etching.

After removing the resist 112, the following regions are formed as impurity regions. Into the formation region of the 3.3 V NMOS transistor, n-type impurities are ion-implanted and the annealing is performed. Thus, an n-type LDD region 123 is formed as an impurity region as shown in FIG. 16. Into the formation region of the 1.2 V NNMOS transistor, p-type impurities are ion-implanted to form a p-type pocket region 133 as an impurity region, and n-type impurities are ion-implanted to form an n-type extension region 134 as an impurity region, as shown in FIG. 16. The above-described annealing may be performed after the ion implantation for forming the pocket region 133 and the extension region 134.

Subsequently, a SiO₂ film 113 is formed over the entire surface using the low-temperature CVD method (about 500° C.) as shown in FIG. 17.

Subsequently, a resist (not shown) is formed over the formation region of the 3.3 V NMOS transistor, and the SiO₂ film 113 over the formation region of the 1.2 V NMOS transistor is removed by the dry etching to form a sidewall composed of the SiO₂ film 113, as shown in FIG. 18. Subsequently, into the formation region of the 1.2 V NMOS transistor, n-type impurities are ion-implanted using as masks the gate electrode 132 and the SiO₂ film 113 over the side wall thereof to form an n-type extension region 135 as an impurity region. Thereafter, the resist over the formation region of the 3.3 V NMOS transistor is removed.

The reason why the formation region of the 3.3 V NMOS transistor is covered with the resist is as follows. That is, when the formation region of the 3.3 V NMOS transistor is etched to expose the Si substrate 110, the low-temperature formed sidewall is disadvantageously brought into contact with the Si substrate 110 in the sidewall formation step performed later again.

Subsequently, using the low-temperature CVD method (about 500° C.), a SiO₂ film 114 is formed over the entire surface and dry-etched, as shown in FIG. 19. Thus, in the formation region of the 3.3 V NMOS transistor, there is formed a sidewall composed of the SiO₂ film 111 formed over the side wall of the gate electrode 122 and over the Si substrate 110 using the thermal oxidation method or the high-temperature CVD method, and the SiO₂ films 113 and 114 formed outside the SiO₂ film 111 using the low-temperature CVD method. In the formation region of the 1.2 V NMOS transistor, there is formed a sidewall composed of the SiO₂ films 113 and 114 formed over the side wall of the gate electrode 132 using the low-temperature CVD method.

Thereafter, using as masks these sidewalls and the gate electrodes 122 and 132, n-type impurities are ion-implanted to form n-type source/drain regions 124 and 136, respectively. Thereafter, the activation annealing at about 1000 to 1200° C. is performed to form silicide layers (not shown) over the surfaces of the gate electrodes 122 and 132 and the source/drain regions 124 and 136. Thus, fundamental structures of the 3.3 V NMOS transistor and the 1.2 V NMOS transistor are completed. Hereafter, a chip having formed thereon the 3.3 V NMOS transistor and the 1.2 V NMOS transistor may be completed through the formations of interlayer insulating films, contact electrodes and wiring layers.

Thus, in the fourth embodiment, the SiO₂ film 111 is formed using the thermal oxidation method or the high-temperature CVD method to construct the sidewall between the LDD region 123 of the 3.3 V NMOS transistor and the low-temperature formed SiO₂ film 113. Therefore, even if hot carriers are generated, accumulation of the hot carriers in the SiO₂ film 111 is suppressed. As a result, depletion of the surface part of the LDD region 123 can be effectively suppressed.

In the fourth embodiment, an n-channel portion of the MOS transistor is described. A p-channel portion thereof may be formed in parallel with the formation of the n-channel portion in accordance with the conventional method.

The first to fourth embodiments are described above; however, a combination of the MOS transistors different in operating voltage is not limited to the above-described examples. Specifically, in addition to a combination of the 3.3 V NMOS transistor and the 1.2 V NMOS transistor, and a combination of the 3.3 V NMOS transistor, the 1.8 V NMOS transistor and the 1.2 V NMOS transistor, the present invention can be similarly applied, for example, to a combination of the 1.8 V NMOS transistor and the 1.2 V NMOS transistor, and a combination of the 3.3 V NMOS transistor and the 1.8 V NMOS transistor. Further, the operating voltages cited here are mere examples, and the above-described principles and formation method can be similarly applied to a combination of the high-voltage transistor and the low-voltage transistor, or a combination of the high-voltage transistor, the medium voltage transistor and the low-voltage transistor.

In the present invention, a first impurity region and a second impurity region which is shallower than the first impurity region and apart from a region under the gate electrode are formed under the sidewall. As a result, depletion of the surface part of the impurity region due to hot carriers accumulated in the sidewall can be suppressed, so that the semiconductor device suppressed in characteristic deterioration can be realized.

Particularly, in the case where the first and second impurity regions have the same conductivity type, when the second impurity region is formed apart from a region under the gate electrode, a transverse electric field in channel can be sufficiently relaxed. Further, in the case where the first and second impurity regions have different conductivity types, the surface part of the first impurity region becomes a previously depleted state due to the second impurity region. As a result, depletion due to hot carriers can be suppressed, so that characteristic deterioration can be suppressed.

Further, in the present invention, the high-voltage transistor and the low-voltage transistor are formed over the same semiconductor substrate and the above-described second impurity region is formed on the high-voltage transistor side by ion implantation. At this time, the ion implantation is performed simultaneously with that for forming the impurity region on the low-voltage transistor side. As a result, a semiconductor device having formed thereon the high-voltage transistor and the low-voltage transistor can be efficiently manufactured at low cost.

Further, in the present invention, a first sidewall is formed over the side wall of the gate electrode and over the impurity region within the semiconductor substrate using a high-temperature formed insulating film, and a second sidewall is formed over the first sidewall using a low-temperature formed insulating film. As a result, accumulation of hot carriers in the first sidewall can be suppressed and depletion of the surface part of the impurity region under the first sidewall can be effectively suppressed, so that a semiconductor device suppressed in characteristic deterioration can be realized.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A semiconductor device having a transistor, the transistor comprising:
a semiconductor substrate;
a gate electrode formed over the substrate through a gate insulating film;
a sidewall formed over a side wall of the gate electrode;
a first impurity region formed in the substrate under the sidewall;
a second impurity region formed in the substrate under the sidewall, the second impurity region being shallower than the first impurity region and being apart from a region under the gate electrode; and
a source/drain region formed outside the first and second impurity regions.

2. The semiconductor device according to claim 1, wherein the second impurity region has a higher impurity concentration than the first impurity region.

3. The semiconductor device according to claim 1, wherein the first and second impurity regions and the source/drain region have the same conductivity type.

4. The semiconductor device according to claim 1, wherein out of the first and second impurity regions and the source/drain region, only the second impurity region has a different conductivity type.

5. The semiconductor device according to claim 1, wherein the sidewall is formed using a insulating film formed at 500° C. or less.

6. The semiconductor device according to claim 1, wherein another transistor operating at a lower voltage than the transistor is formed over the substrate, the another transistor having an impurity region with an impurity profile the same as that of the second impurity region of the transistor.

7. A semiconductor device having a transistor, the transistor comprising:
a semiconductor substrate;
a gate electrode formed over the substrate through a gate insulating film;
a first sidewall formed over a side wall of the gate electrode and over the semiconductor substrate using a first insulating film;
a second sidewall formed over the first sidewall using a second insulating film;
an impurity region formed in the substrate under the first sidewall; and
a source/drain region formed outside the impurity region.

8. The semiconductor device according to claim 7, wherein another transistor operating at a lower voltage than the transistor is formed over the substrate, the another transistor having a sidewall where at least a portion in contact with the substrate is composed only of the second insulating film.

9. A method of manufacturing a semiconductor device having transistors different in operating voltage, the method comprising the steps of:
forming gate electrodes through gate insulating films in a formation region of a high-voltage transistor operating at a higher voltage and in a formation region of a low-voltage transistor operating at a lower voltage of a semiconductor substrate, respectively;
ion-implanting impurities into the high-voltage transistor formation region having formed thereover the gate electrode to form a first impurity region;
forming a first sidewall over the high-voltage transistor formation region having formed therein the first impurity region;
simultaneously ion-implanting impurities into the high-voltage transistor formation region having formed thereover the first sidewall and the low-voltage transistor formation region to form second impurity regions shallower than the first impurity region;
forming second sidewalls over the high-voltage transistor formation region and low-voltage transistor formation region having formed therein the second impurity region, respectively; and
ion-implanting impurities into the high-voltage transistor formation region and the low-voltage transistor formation region having formed thereover the second sidewalls to form source/drain regions.

10. The method according to claim 9, wherein in the step of forming the second impurity region, the region is formed to have a higher impurity concentration than the first impurity region.

11. The method according to claim 9, wherein the impurities ion-implanted in the step of forming the first impurity region, in the step of forming the second impurity region and in the step of forming the source/drain region have the same conductivity type.

12. The method according to claim 9, wherein the impurities ion-implanted in the step of forming the first impurity region, in the step of forming the second impurity region and in the step of forming the source/drain region, only the impurities ion-implanted in the step of forming the second impurity region have a different conductivity type.

13. The method according to claim 9, wherein in the step of forming the first sidewall, the sidewall is formed using a insulating film formed at 500° C. or less.

14. The method according to claim 9, wherein in the step of forming the second sidewall, the sidewall is formed using a insulating film formed at 500° C. or less.

15. The method of manufacturing a semiconductor device according to claim 9, further comprising the step of, before or after the step of forming the first impurity region, ion-implanting impurities into the low-voltage transistor formation region having formed thereover the gate electrode.

16. A method of manufacturing a semiconductor device comprising:
forming a first gate electrode in a first region of a semiconductor substrate;
forming a second gate electrode in a second region of the semiconductor substrate;
forming a resist film over the first region;
implanting first impurities into the semiconductor substrate using the second gate electrode and the resist film as masks;
eliminating the resist film;
forming a first sidewall over the side wall of the first gate electrode and the second gate electrode; and
implanting second impurities into the semiconductor substrate using the first gate electrode, the second gate electrode, and the first sidewall as masks.

17. The method of manufacturing the semiconductor device according to claim 16, wherein a gate length of the first gate electrode is longer than a length of the second gate electrode.

18. The method of manufacturing the semiconductor device according to claim 16, wherein a depth of a region of the second impurities is deeper than a depth of a region of the first impurities.

19. The method of manufacturing the semiconductor device according to claim 16, further comprising:
implanting third impurities into the semiconductor substrate using the first gate electrode as a mask.

20. The method of manufacturing the semiconductor device according to claim 16, further comprising:
forming a second sidewall over the first sidewall of the first gate electrode and the second gate electrode after the executing the second ion-implanting;
implanting forth impurities into the semiconductor substrate using the first gate electrode, the second gate electrode, and the second sidewall as masks.
